(19) United States
(12) Patent Application Publication
(10) Pub. No.: US 2026/0033311 A1
(43) Pub. Date: Jan. 29, 2026

(54) TRANSCEIVER WITH ON-PACKAGE ANTENNA

(71) Applicant: Texas Instruments Incorporated, Dallas, TX (US)

(72) Inventor: Nolan Riley, ALLEN, TX (US)

(21) Appl. No.: 18/780,484

(22) Filed: Jul. 23, 2024

(51) Int. Cl. H01L 23/485; H01L 23/00; H01Q 1/22; H01Q 21/00; H04B 1/00; H04B 1/40

(52) U.S. Cl. CPC H01L 23/485; H01L 24/08; H01L 24/16; H01Q 1/2283; H01Q 21/0006; H04B 1/0003; H04B 1/40; H01L 2224/08112; H01L 2224/16257; H01L 2924/14215

(57) ABSTRACT

In described examples, an integrated circuit (IC) package includes first and second external connectors at an external surface of the IC package, an IC die, and an antenna. The IC die is coupled to the first external connector. The antenna is coupled to the second external connector. The IC die and the antenna are not coupled within the IC package.

### TECHNICAL FIELD

This application relates generally to transceiver systems, and more particularly to integrated circuit (IC) packages with on-package antennas.

### BACKGROUND

A radar system senses objects by emitting electromagnetic waves using one or more transmitter antennas and receiving reflections of the electromagnetic waves using one or more receiver antennas. Control of the transmitted signals and processing of the received signals may be performed by a number of active and passive IC devices on one or more IC dies. The dies and devices may be incorporated into one or more semiconductor packages. A semiconductor package surrounds and protects the incorporated IC dies and/or devices. The package may include layers of rigid insulating material and layers of conductive material that extend through the insulating material to connect the dies and devices to each other and to the remainder of the system.

In some examples, a package includes circuits for control of transmitted signals and/or circuits for processing received signals. The package may also include one or more antennas. Alternatively, the package may be mounted on a printed circuit board (PCB) and connected via traces on the PCB to one or more antennas that are also mounted on the PCB.

### SUMMARY

In described examples, an IC package includes first and second external connectors at an external surface of the IC package, an IC die, and an antenna. The IC die is coupled to the first external connector. The antenna is coupled to the second external connector. The IC die and the antenna are not coupled within the IC package.

### BRIEF DESCRIPTION OF THE DRAWINGS

FIG. 1 is a functional block diagram of an example radar system.

FIG. 2 is a cross-sectional functional block diagram of a radar system including an on-package antenna and a PCB-mounted antenna.

FIG. 3A is a first cross-sectional view of the IC package and PCB of FIG. 2.

FIG. 3B is a second cross-sectional view of the IC package and PCB of FIG. 2.

### DETAILED DESCRIPTION

Radar systems can be used for various applications, such as industrial and automotive applications. A radar system includes a number of transmitter signal chain(s), a receiver signal chain(s), and antenna(s). Each of the transmitter signal chains controls a signal to be transmitted by at least one of the antennas. Each of the receiver signal chains manipulates a signal reflected off an object within range of a field of view (FOV) of the radar system and received by at least one of the antennas. Specifically, a receiver signal chain manipulates the received signal to produce data that can be analyzed by a processor to determine range, angle, and velocity of the object.

An IC die can be manufactured to include portions or an entirety of a transmitter signal chain and/or a receiver signal chain. The same IC die can be packaged, and that IC package can include an antenna-on-package.

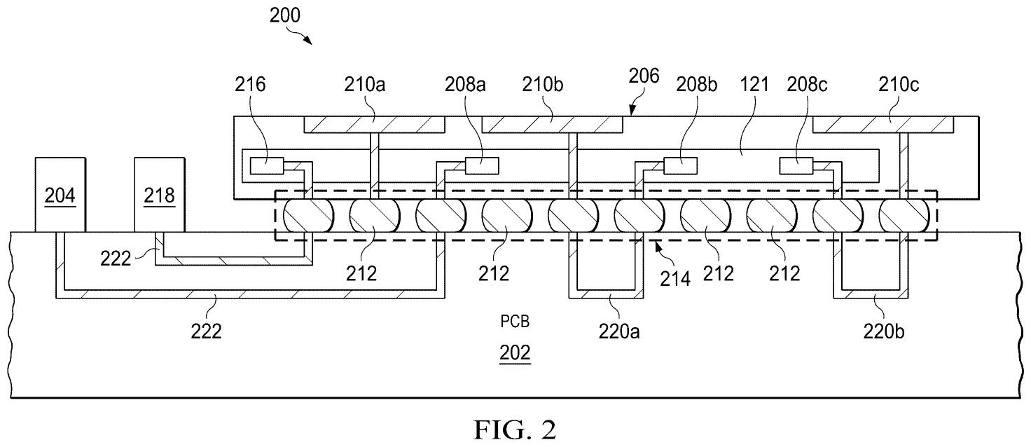

An IC package is described with respect to FIG. 2 in which an antenna-on-package and a transceiver signal chain are each separately connected to external connective structures of the IC package, such as a pin, ball, lead, or wire, and are not connected to each other within the body of the IC package. This can enable various benefits including some or all of improved application flexibility of the IC package 206, simplified design of the IC package 206, simplified design of an IC die, improved design flexibility at the PCB level, or reduced system cost.

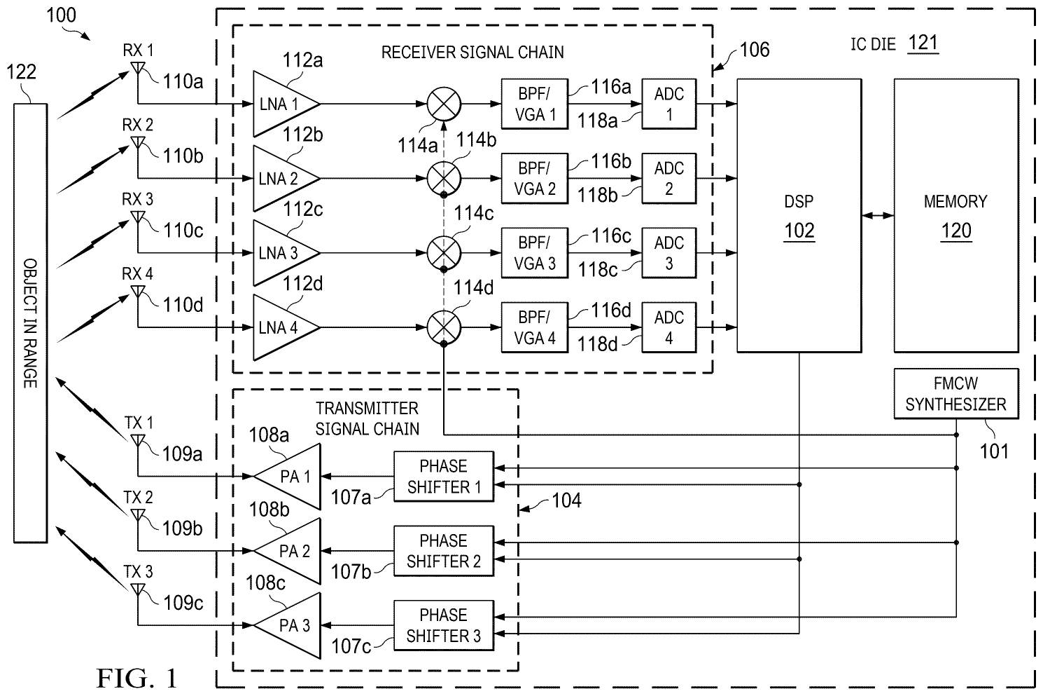

FIG. 1 is a functional block diagram of an example radar system 100 for transmitting a radar signal and receiving a reflected radar signal. In particular, the radar system 100 is a frequency modulated continuous wave (FMCW) radar system. FMCW radar systems transmit a series of “chirps,” which are signals that have frequencies that vary over time. Chirps to be transmitted by different antennas of a radar system can be differentiated, using various protocols, to enable a corresponding receiver signal chain to determine which portion of a received signal corresponds to which transmitter antenna. Example differentiation protocols include Doppler division multiple access (DDMA), time division multiple access (TDMA), and Binary Phase Modulation (BPM). Thus in one example, the radar system 100 is a DDMA FMCW radar system.

In some examples, a DDMA FMCW radar system, or an FMCW radar system using another type of transceiver protocol (such as TDMA or BPM), or a different type of radar system, uses different functional blocks. In some examples, the radar system 100 is configured to use millimeter wave sensing or sub-terahertz (sub-THz) sensing. In some examples, the radar system 100 uses millimeter wave sensing that transmits chirps in a 60 gigahertz or 77 gigahertz band. In some examples, the radar system 100 uses sub-THz sensing that transmits chirps in a 140 gigahertz (GHz) or higher band.

The radar system 100 includes an FMCW synthesizer 101 (a signal generator), a digital signal processor (DSP) 102, a transmitter signal chain 104, a receiver signal chain 106, transmitter antennas 109, receiver antennas 110, and a memory 120. In some examples, all or a portion of the FMCW synthesizer 101, the DSP 102, the transmitter signal chain 104, the receiver signal chain 106, and the memory 120 are fabricated together on an IC die 121.

The transmitter antennas 109 include a first transmitter antenna (TX1) 109a, a second transmitter antenna (TX2) 109b, and a third transmitter antenna (TX3) 109c. The receiver antennas 110 include a first receiver antenna (RX1) 110a, a second receiver antenna (RX2) 110b, a third receiver antenna (RX3) 110c, and a fourth receiver antenna (RX4) 110d.

The FMCW synthesizer 101, which may include an oscillator and a phase locked loop, may be configured to generate radar-frequency signals such as chirps, signals with linearly increasing or decreasing frequency. These signals may be provided by the FMCW synthesizer 101 to the transmitter signal chain 104. The transmitter signal chain 104 includes phase shifters 107 and power amplifiers 108. The transmitter signal chain 104 can also be described as including the FMCW synthesizer 101. The phase shifters 107 include a first phase shifter (phase shifter 1) 107a, a second phase shifter (phase shifter 2) 107b, and a third phase shifter (phase shifter 3) 107c that each independently shift the phase of a respective copy of the signal provided by the FMCW synthesizer 101. The power amplifiers 108 include a first power amplifier (PA1) 108a, a second power amplifier (PA2) 108b, and a third power amplifier (PA3) 108c.

The receiver signal chain 106 includes low noise amplifiers (LNAs) 112, mixers 114, band pass filter (BPF) and variable gain amplifier (VGA) circuits (BPF/VGA circuits) 116, and analog-to-digital converter (ADC) circuits 118. The receiver signal chain 106 can also be described as including the FMCW synthesizer 101.

The LNAs 112 include a first LNA (LNA1) 112a, a second LNA (LNA2) 112b, a third LNA (LNA3) 112c, and a fourth LNA (LNA4) 112d. The mixers 114 include a first mixer 114a, a second mixer 114b, a third mixer 114c, and a fourth mixer 114d. The BPF/VGA circuits 116 include a first BPF/VGA circuit (BPF/VGA 1) 116a, a second BPF/VGA circuit (BPF/VGA 2) 116b, a third BPF/VGA circuit (BPF/VGA 3) 116c, and a fourth BPF/VGA circuit (BPF/VGA 4) 116d. The ADC circuits 118 include a first ADC circuit (ADC 1) 118a, a second ADC circuit (ADC 2) 118b, a third ADC circuit (ADC 3) 118c, and a fourth ADC circuit (ADC 4) 118d.

The FMCW synthesizer 101 generates chirps to be transmitted, such as for object detection and range, angle, and velocity determination. The FMCW synthesizer 101 outputs the chirps to respective first inputs of the phase shifters 107, and also to first inputs of respective mixers 114. In some examples, the FMCW synthesizer 101 can be described as providing an input to the transmitter signal chain 104, and a first input to the receiver signal chain 106.

The phase shifters 107 phase shift the chirps using respective phase shift code vectors to enable DDMA differentiation. The phase shifters 107 output the phase shifted chirps to respective power amplifiers 108. The power amplifiers 108 amplify the respective phase shifted chirp signals and output the amplified signals to respective transmitter antennas 109. In some examples, the transmitter antennas 109 can be described as receiving an output of the transmitter signal chain 104.

The transmitter antennas 109 transmit the amplified, phase shifted chirps. In some examples, the transmitted signals are reflected by an object 122 that is within the FOV and the detection and range, angle, and velocity determination range of the radar system 100 (object in range 122).

The reflected signals are received by the receiver antennas 110. The receiver antennas 110 output the received signals to respective LNAs 112, which amplify the received signals. In some examples, the receiver antennas 110 can be described as providing a second input to the receiver signal chain 106.

The LNAs 112 output the amplified signals to second inputs of respective mixers 114. The mixers 114 output the mixed signals to respective BPF/VGA circuits 116 which filter and amplify the mixed signals. The BPF/VGA circuits 116 output the resulting cleaned signals to respective ADC circuits 118, which sample the cleaned mixed signals to generate respective data sets made up of digital samples. The ADC circuits 118 output the digital samples to the DSP 102 for analysis. In some examples, the DSP 102 can be described as receiving an output of the receiver signal chain 106.

The DSP 102 uses the digital samples to determine presence, range, angle, and velocity of the object in range 122. Herein, object in range refers to an object that is both within a shared FOV of the transmitter antennas 109 and corresponding receiver antennas 110, and within a designed range over which a corresponding radar system (such as the radar system 100 of FIG. 1) can detect objects using received reflected signals.

For example, object presence may be determined based on a signal amplitude greater than a threshold. Range may be determined by a unique range frequency corresponding to the signal's round trip delay multiplied by a frequency slope of a transmitted chirp. Velocity may be determined by the phase variation of the unique range frequency over multiple chirps, which manifests as a unique Doppler frequency. Angle may be determined by the phase variation for a particular received chirp across different receiver paths in the receiver signal chain 106, caused by the difference in time of flight across the different receivers. A spectral estimation technique such as a fast Fourier transform (FFT) may be applied to the digital samples provided by the ADCs 118 to enable these determinations.

FIG. 2 is a cross-sectional view and functional block diagram of a radar system 200 including a PCB 202 with a PCB-mounted antenna 204 thereon, and an IC package 206 with multiple transceiver circuits 208 and multiple on-package antennas 210. The IC package 206 includes a first transceiver circuit 208a, a second transceiver circuit 208b, and a third transceiver circuit 208c, a first on-package antenna 210a, a second on-package antenna 210b, a third on-package antenna 210c, a set of external connectors (e.g., multiple solder balls 212 that together form a ball grid array (BGA) 214), and additional IC circuits 216. In some examples, other external conductive connectors such as a pin, pad, ball, or lead exposed on the surface of the IC package 206 are used. The PCB includes additional PCB circuits 218. In some examples, the transceiver circuits 208 and additional IC circuits 216 are included in an IC die 121.

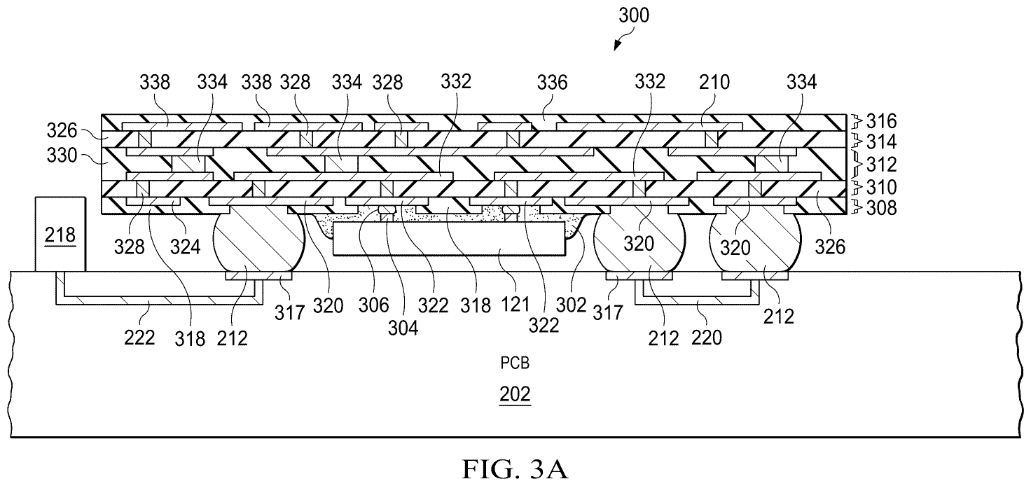

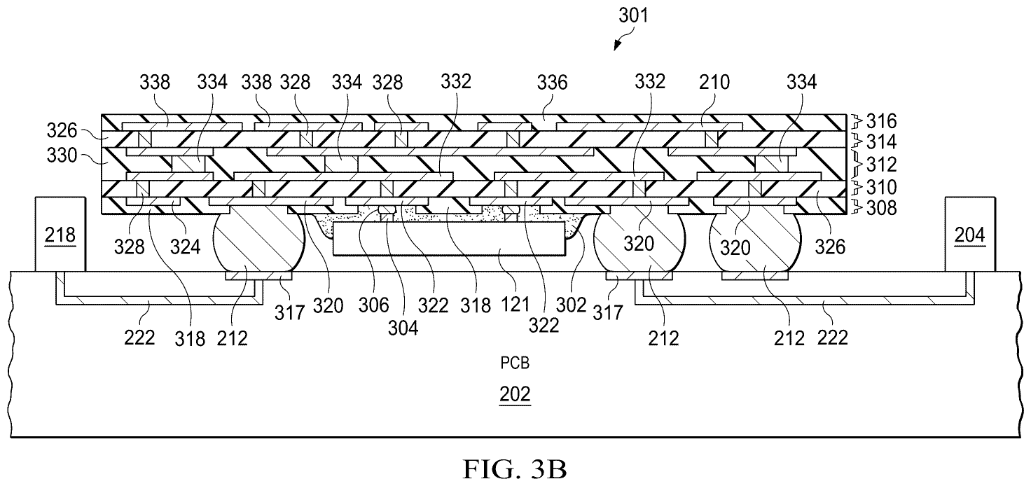

In some examples, the transceiver circuits 208 correspond to the transmitter signal chain 104 and the receiver signal chain 106 and are fabricated on one or more IC dies 121 incorporated into the IC package 206. Layer structure of an IC package 206, including incorporation of an IC die 121 into the IC package 206, is further described with respect to FIG. 3. In some examples, different ones of the transceiver circuits 208 correspond to different portions of the transmitter signal chain 104 or the receiver signal chain 106.

In some examples, an IC package 206 includes more or fewer transceiver circuits 208. In some examples, portions of a transmitter signal chain 104 or a receiver signal chain 106 are fabricated on more than one IC die 121 within the IC package 206, or are fabricated on a die in a different IC package 206, or are connected to or via traces 222 of the PCB 202. Transceiver circuits 208 are connected to respective solder balls 212 of the BGA 214.

The on-package antennas 210 are located on or near an exterior side of the IC package 206. The antennas 210 are connected to respective solder balls 212 of the BGA 214. The solder balls 212 to which the antennas 210 are connected are not the same solder balls 212 as those to which the transceiver circuits 208 are connected. The transceiver circuits 208 are not electrically connected to the antennas 210 by a conductive route within the IC package 206.

As described above, circuitry of the IC package 206 includes the transceiver circuits 208 and the antennas 210. Herein, circuitry of the PCB 202 includes traces 222 and other conductive lines of the PCB 202, as well as RLC circuits, ICs, and other electrical features fabricated or mounted on or penetrating within the PCB 202. Circuitry of the IC package 206 is connected to circuitry of the PCB 202 via the BGA 214. In the illustrated example, the first transceiver circuit 208a is connected to the PCB-mounted antenna 204 via traces 222 of the PCB 202. The second transceiver circuit 208b is connected to the second on-package antenna 210b via a first loopback path 220a. And the third transceiver circuit 208c is connected to the third on-package antenna 210c via a second loopback path 220b. The first on-package antenna 210a is not connected to a transceiver circuit 208, and accordingly, is not used during signal transmission, reception, and processing.

The additional IC circuits 216 are connected to the additional PCB circuits 218 via traces 222 on the PCB 202. In some examples, the additional IC circuits 216 correspond to the FMCW synthesizer 101 (or other signal generator) or the DSP 102. In some examples, the additional PCB circuits 218 correspond to input circuits to provide data to the DSP 102, output circuits to receive data, processed range, angle, and/or velocity information, a point cloud, or similar information from the DSP 102, or control circuits to provide frequency, phase, sample rate, or other control signals to the IC die 121 (accordingly, to the radar system 100).

Loopback paths 220 are conductive lines external to the IC package 206, such as traces 222 on the PCB 202. A loopback path 220 connects one of the solder balls 212 to another solder ball 212. In some examples, a first solder ball 212 is connected to a second solder ball 212 via a conductive line that is not mounted or fabricated on or penetrating within a PCB 202, such as a lead or wire. Loopback paths 220 enable circuits that are part of the IC package 206, and that are not connected to each other within the IC package 206, to be connected to each other.

Accordingly, a transceiver circuit 208 can be connected to an on-package antenna 210 via respective conductive layers within the IC package 206, solder balls 212, and loopback paths 220. As described above, moving a portion of the connection between the transceiver circuit 208 and the on-package antenna(s) 210 outside of the IC package 206 provides various benefits including some or all of improved application flexibility of the IC package 206, simplified design of the IC package 206, simplified design of an IC die 121, improved design flexibility at the PCB 202 level, or reduced system cost.

Also, in some examples a designer or supplier of IC packages that include a transmitter and/or receiver signal chain(s) has a design process that prefers to address antennas external to the IC package first. Moving a portion of the connection between the transceiver circuit 208 and the on-package antenna(s) 210 outside of the IC package 206 provides a downstream vendor or a customer a variety of options. Such options include use of the transceiver circuit 208 with one or more antennas-on-package, with one or more antennas on the PCB 202 or otherwise external to the package, or a combination thereof.

FIG. 3A is a first cross-sectional view 300 of the IC package 206 and PCB 202 of FIG. 2. FIG. 3B is a second cross-sectional view 301 of the IC package 206 and PCB 202 of FIG. 2. FIG. 3A corresponds to an example in which a loopback path 220 of the PCB 202 connects the IC die 121 to an antenna-on-package 210. FIG. 3B corresponds to an example in which a trace 222 of the PCB 202 connects the IC die 121 to a PCB-mounted antenna 204.

The IC package 206 includes an underfill material 302 that mechanically connects the IC die 121 to the rest of the IC package 206, conductive pillars 304 and solder 306 that electrically connect the IC die 121 to other circuits of the IC package 206. The IC package 206 also includes a number of layers of dielectric material (e.g., Ajinomoto build-up film and/or other suitable dielectric material), such as a first surface layer 308, a first buildup dielectric layer 310, a core dielectric layer 312, a second buildup dielectric layer 314, and a second surface layer 316. The IC package 206 includes various vias and interconnects, which in some examples are or include copper disposed among the layers of dielectric materials. Vias connect interconnects and other conductive structures in different horizontally-oriented layers. The BGA 214 is connected to traces 222 of the PCB 202 via conductive pads 317, such as copper pads, fabricated on or exposed on the surface of the PCB 202

The IC die 121 is connected to conductive pillars 304, such as copper pillars or full solder ball interconnects. In some examples, a solder cap 306 is used with conductive pillars 304. The solder cap 306 is, for example, tin solder that includes a low percentage of silver. The first surface layer 308 includes solder resist 318, BGA pads 320, flip chip interconnect pads 322, and other routing 324. The solder resist 318 is made of dielectric material and defines regions where solder can or cannot wet (electrically connect) to copper. The other routing 324 connects circuits within the IC package 206, and is also referred to as signal traces. The BGA 214 is connected to the BGA pads 320, and the solder cap 306 is connected to the flip chip interconnect pads 322.

The first and second buildup dielectric layers 310 and 314 each include buildup dielectric material 326 and buildup vias 328. In some examples, buildup dielectric material 326 is or includes prepregnated film or other composite buildup film. Buildup vias 328 of the first buildup layer 310 connect BGA pads 320, interconnect pads 322, and/or other routing 324 of the first surface layer 308 to interconnects of the core dielectric layer 312.

The core dielectric layer 312 includes core dielectric 330, core interconnects 332, and core vias 334. In some examples, core dielectric 330 is or includes prepregnated core material. The second surface layer 316 includes solder resist 336, an antenna-on-package 210, and other structures 338 that may include antennas-on-package and/or electrical bandgap structures that isolate signals of different on-package antenna from each other. Buildup vias 328 connect between core interconnects 332 and the antenna-on-package 210 and/or other structures 338 at locations defined by the solder resist 336 of the second surface layer 316. Solder resist 336 of the second surface layer 316 also protects antennas-on-package 210 from oxidation and unwanted electrical connections.

In some examples, a processor other than a DSP is used, such as a central processing unit (CPU) or a microcontroller unit (MCU).

In some examples, an IC package 206 includes multiple antennas-on-package. In some examples, one or more of the antennas-on-package is coupled to the IC die 121 within the IC package 206.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, and “interconnection” are used interchangeably. Unless specifically stated to the contrary, these terms are generally used to mean an interconnection between or a terminus of a device element, a circuit element, an integrated circuit, a device or other electronics or semiconductor component.

While certain elements of the described examples may be included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit.

Modifications are possible in the described examples, and other examples are possible within the scope of the claims.

What is claimed is:

1. An integrated circuit (IC) package comprising:
first and second external connectors at an external surface of the IC package;
an IC die electrically coupled to the first external connector; and
an antenna electrically coupled to the second external connector;
wherein the IC die and the antenna are not electrically coupled within the IC package.

2. The IC package of claim 1, wherein the first external connector and the second external connector are adapted to be connected to each other.

3. The IC package of claim 1, wherein the first and second external connectors each include one or more of a pin, pad, ball, or lead exposed on a surface of the IC package.

4. The IC package of claim 1, wherein the IC die includes one or more of a transmitter signal chain or a receiver signal chain.

5. The IC package of claim 4, wherein the IC die includes one or more of a processor or a signal generator.

6. The IC package of claim 4, wherein the transmitter signal chain includes a power amplifier.

7. The IC package of claim 4, wherein the receiver signal chain includes one or more of a low noise amplifier, a mixer, a band pass filter, a variable gain amplifier, or an analog-to-digital converter.

8. The IC package of claim 1, wherein the IC die includes one or more of a digital signal processor (DSP), a central processing unit (CPU), or a microcontroller unit (MCU).

9. The IC package of claim 1, wherein the antenna is a first antenna, further comprising:
third and fourth external connectors at the external surface of the IC package; and
a second antenna electrically coupled to the third external connector;
wherein the IC die is electrically coupled to the fourth external connector; and
wherein the IC die and the second antenna are not electrically coupled within the IC package.

10. A system comprising:
a printed circuit board (PCB) including a first circuit; and
an integrated circuit (IC) package that includes:
first, second, and third external connectors;
an IC die coupled to the first and second external connectors; and
an antenna coupled to the third external connector;
wherein the IC die and the antenna are not coupled within the IC package; and
wherein the first circuit is coupled to the second external connector.

11. The system of claim 10,
wherein the PCB includes a conductive line having a first terminal and a second terminal;
wherein the first terminal of the conductive line is coupled to the first external connector; and
wherein the second terminal of the conductive line is coupled to the third external connector.

12. The system of claim 11, wherein the conductive line includes one or more of a trace, a wire, or a lead.

13. The system of claim 10, wherein the first external connector and the third external connector are adapted to be connected to each other.

14. The system of claim 10, wherein the first external connector and the third external connector are connected to each other via a trace of the PCB.

15. The system of claim 10, wherein the first, second, and third external connectors include one or more of a pin, pad, ball, or lead exposed on a surface of the IC package.

16. The system of claim 10, wherein the IC die includes one or more of a transmitter signal chain or a receiver signal chain.

17. The system of claim 16, wherein the IC die includes one or more of a processor or a signal generator.

18. The system of claim 16, wherein the transmitter signal chain includes a power amplifier.

19. The system of claim 16, wherein the receiver signal chain includes one or more of a low noise amplifier, a mixer, a band pass filter, a variable gain amplifier, or an analog-to-digital converter.

20. The system of claim 10, wherein the antenna is a first antenna, further comprising:
fourth and fifth external connectors of the IC package; and
a second antenna coupled to the fourth external connector;
wherein the IC die is coupled to the fifth external connector; and
wherein the IC die and the second antenna are not coupled within the IC package.
